(19) United States
(12) Patent Application Publication
(10) Pub. No.: US 2026/0219303 A1
(43) Pub. Date: Jul. 30, 2026

(54) Determining State of Current Sensor for Battery

(71) Applicant: LG Energy Solution, Ltd., Seoul (KR)

(72) Inventor: Myeong Hui Park, Daejeon (KR)

(73) Assignee: LG Energy Solution, Ltd., Seoul (KR)

(21) Appl. No.: 19/148,765

(22) PCT Filed: Jun. 21, 2024
(86) PCT No.: PCT/KR2024/008587

§ 371 Date: Jul. 17, 2025

(30) Foreign Application Priority Data
Sep. 7, 2023 (KR) 10-2023-0118864

(51) Int. Cl. G01R 19/165; B60L 58/12; B60L 58/16; G01R 1/20; G01R 19/00; G01R 31/385

(52) U.S. Cl. CPC G01R 19/16542; B60L 58/12; B60L 58/16; G01R 1/203; G01R 19/0092; G01R 31/385; B60L 2240/549; B60L 2260/44

(57) ABSTRACT

The technology generally relates to accurately determining whether a current sensor of a battery pack is abnormal while determining a current validity of the battery pack through the current sensor. Determining whether the current sensor is sensor is based on measuring a consumption current of a battery management system for the battery pack.

### CROSS-REFERENCE TO RELATED APPLICATIONS

This application is a national phase entry under 35 U.S.C. § 371 of International Application No. PCT/KR2024/008587, filed on Jun. 21, 2024, which claims priority to Korean Patent Application No. 10-2023-0118864, filed on Sep. 7, 2023, all of which is incorporated herein by reference.

### BACKGROUND

Two current sensors can be used to evaluate the current validity a battery pack. A current sensor is connected to each terminal of the battery pack, e.g., the cathode terminal and the anode terminal. The current validity of the battery pack is evaluated using the difference in the measurement results of the two current sensors. However, using two current sensors is costly and can create difficulties in reducing the size of the battery pack.

### BRIEF SUMMARY

The technology generally relates to accurately determining whether a current sensor of a battery pack is abnormal while determining a current validity of the battery pack through the current sensor. Determining whether the current sensor is sensor is based on measuring a consumption current of a battery management system for the battery pack.

Aspects of the disclosure provide for a battery module including: a battery pack; a current sensor including a current detecting resistor electrically connected to a current path formed by the battery pack; and a battery controller configured to control the battery pack and determine whether the current sensor is abnormal based on a measurement result of the current sensor; wherein the current detecting resistor has one end that is connected to the battery pack and another end that is connected to a ground line of the battery controller.

In some examples, the battery controller may be further configured to determine that the current sensor is in an abnormal state based on the measurement result of the current sensor being equal to or below a threshold value.

In some examples, the battery controller may be further configured to notify a vehicle controller of the abnormal state of the current sensor based on a determination that the current sensor is in the abnormal state.

In some examples, the battery controller may be further configured to control a relay to open at least a part of the current path of the batty pack based on the determination that the current sensor is in the abnormal state.

In some examples, the threshold value may be determined based on a consumption current of the battery controller.

In some examples, an expected consumption current range of the battery controller may be set for each operation mode of the battery pack.

In some examples, the battery controller may be further configured to: based on the measurement result of the current sensor, determine an operation mode of the battery pack; identify an expected consumption current range of the battery controller corresponding to the operation mode of the battery pack; based on the identified expected consumption current range, correct the measurement result of the current sensor; and notify a vehicle controller of the corrected measurement results.

In some examples, the battery controller may be further configured to: based on the measurement result of the current sensor exceeding the threshold value, determine that the current sensor is in a normal state; and, based on a determination that the current sensor is in the normal state, control the battery pack to supply power to a vehicle.

In some examples, the battery controller may be further configured to, by applying the measurement result of the current sensor to a SoX process, obtain information on a battery state.

In some examples, the SoX process may include at least one of a state of charge (SoC) process, a state of power (SoP) process, or a state of health (SoH) process, and the information on the battery state may respectively include at least one of a battery SoC, a battery SoP, or a battery SoH.

In some examples, the current detecting resistor may be a shunt resistor.

In some examples, the battery controller may be further configured to: before supplying an amount of power to a motor of the vehicle, control a relay for the current path of the battery pack to form a closed circuit; and, while the motor of the vehicle is not running, determine a state of the current sensor based on the measurement result of the current sensor.

Aspects of the disclosure provide for a method of determining a state of a current sensor by a battery controller included in a battery module, the method including: receiving a measurement result of a current sensor including a current detecting resistor electrically connected to a current path that formed by a battery pack; and, based on the measurement result of the current sensor, determining whether the current sensor is abnormal; wherein the current detecting resistor has one end that is connected to the battery pack and another end that is connected to a ground line of the battery controller.

### BRIEF DESCRIPTION OF DRAWINGS

FIG. 1 is a block diagram of a battery module according to aspects of the disclosure.

FIGS. 2A and 2B are circuit diagrams of a battery module according to aspects of the disclosure.

FIG. 3 is a flow diagram of a battery module according to aspects of the disclosure.

FIG. 4 is a flow diagram of a battery module according to aspects of the disclosure.

FIG. 5 is a flow diagram of a battery module according to aspects of the disclosure.

FIG. 6 is a flow diagram of a battery module according to aspects of the disclosure.

### DETAILED DESCRIPTION

The technology generally relates to accurately determining whether a current sensor of a battery pack is abnormal while determining a current validity of the battery pack through the current sensor. Determining whether the current sensor is sensor is based on measuring a consumption current of a battery management system for the battery pack.

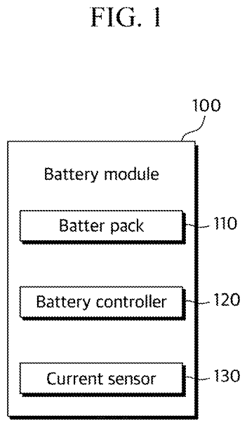

FIG. 1 is a block diagram of a battery module 100 according to aspects of the disclosure. The battery module 100 may also be called a battery system. The battery module 100 may include a battery pack 110, a battery controller 120, and a current sensor 130. The battery pack 110 may store electrical energy to power a vehicle, such as an electric vehicle and/or a hybrid vehicle. The battery controller 120 may manage and control the battery pack 110 and other components (not shown) to supply other currents.

While one battery pack 110 is shown in FIG. 1, the battery module 100 may include any number of battery packs 110, e.g., two or more battery packs.

Some components included in the battery module 100 may be omitted, or other components may be added to the battery module 100. Additionally, or alternatively, some components within the battery module 100 may be implemented in an integrated manner or may be implemented as singular or multiple entities. At least some of the components within the battery module 100 may be interconnected via a controller area network (CAN), a bus, general purpose input/output (GPIO), a serial peripheral interface (SPI), or a mobile industry processor interface (MIPI), and may transmit and/or receive data and/or signals.

The battery pack 110 according to an example embodiment may include multiple batteries connected in series. The number of batteries included in the battery pack 110 may be two or more. Each battery may include multiple battery cells connected in parallel. The number of battery cells contained in each battery may be two or more. The battery pack 110 may perform a charging operation or a discharging operation by being connected to a load, such as a power consuming device, through the cathode terminal and anode terminal. A plurality of battery cells and a plurality of batteries may be connected in parallel and series in various ways to meet the specifications of the load.

The battery cell may be, for example, a lithium ion battery cell.

The battery pack 110 may be an electrical energy source that provides electrical energy to the power consuming device to power the power consuming device. Example power consuming devices include mobility devices such as electric vehicles, hybrid vehicles, and/or electric scooters. The battery pack 110 may supply power to a vehicle under the control of the battery controller 120, and may also be powered from a charging device.

The battery controller 120 may be a battery management system (BMS) that manages and controls the battery pack 110. The battery controller 120 may be called a BMS, a battery control circuit, or a battery monitoring integrated circuit. The battery controller 120 is connected to the battery pack 110 and may obtain voltage signals measured from both ends of the battery pack 110. For example, the battery controller 120 may be connected to each of multiple batteries included in the battery pack 110.

The current sensor 130 may be a sensor including a current detecting resistor. The current detecting resistor may be, for example, a shunt resistor. For example, the current sensor 130 may include a shunt resistor and a high-speed amplifier and has the advantages of being simple to install in the current path and easy to handle. The current sensor 130 may measure the total current value flowing through the current sensor 130 by connecting the shunt resistors in parallel to a constant current circuit, e.g., an ammeter.

For example, the current measurement range may be expanded by using the current sensor 130 with shunt resistors connected in parallel. The current sensor 130 may detect a voltage drop across both terminals of the shunt resistor by connecting the shunt resistors in series with the ammeter. The battery controller 120 may measure the current of the battery pack 110 by converting the voltage measured by the current sensor 130 into current. For example, since the resistance value of the shunt resistor is known in advance, when the voltage values at both ends of the shunt resistor are measured, the current sensor 130 may calculate the current value flowing through the shunt resistor, and this current value may be the current value flowing in a charge/discharge path of the battery pack 110. Measuring the current value is based on Ohm's law, and the exact current value may be measured by using the law that voltage changes proportionally to current.

The current sensor 130 may be electrically connected to a current path formed by the battery pack 110. For example, the current sensor 130 may be installed on the current path connected to the anode terminal, e.g., (−) terminal, among the two terminals of the battery pack 110. The current sensor 130 is connected to the battery controller 120 and may transmit a measurement result to the battery controller 120.

The battery controller 120 may control or manage the battery pack 110. The battery controller 120 may monitor the voltage, current, and/or temperature of the battery pack 110. The battery controller 120 may perform abnormal diagnosis, cell balancing, and/or estimating a state of charge (SoC), a state of health (SoH), and/or a state of power (SoP) of the battery pack 110. The SoC is a percentage expression of the current charge state of the battery, the SoH is a percentage expression of the current degradation state of the battery, and the SoP is a ratio that expresses the current power state of the battery. The battery controller 120 may receive a measurement result from the current sensor 130 and, based on the measurement result, detect the current state of the battery pack 110. The battery controller 120 may also detect the state of the current sensor 130 based on the measurement result of the current sensor 130.

The battery module 100 may further include a relay (not shown). The relay may, under the control of the battery controller 120, open at least a part of the current path of the battery pack 110 to prevent current from flowing, and may also be used to connect the current path of the battery pack 110 to form a closed circuit.

The battery controller 120 may transmit information about the battery pack 110 to a vehicle controller (not shown). The vehicle controller may be, for example, an electronic control unit (ECU). A vehicle controller may refer to a control device that controls various states of a vehicle. The battery controller 120 may include a communication module for communicating with other systems within the vehicle, e.g., a vehicle controller. The communication module of the battery controller 120 may communicate with other systems in the vehicle using a controller area network (CAN). Components within the battery controller 120 may also be connected to each other through a CAN bus. The CAN communication refers to a communication to allow controllers or devices to communicate with each other in a vehicle without a host computer. As a non-host bus message-based network protocol mainly used for communication between each controller, the CAN communication may be mainly used in vehicles. The communication module of the battery controller 120 may include a buffer that temporarily stores data received from other modules or systems.

For example, the battery controller 120 may notify information about the battery pack 110, including voltage, current, temperature, a SoC, a SoH, and/or a SoP of the battery pack 110, to the vehicle controller. The battery controller 120 may notify the state of components included in the battery module 100. For example, when an abnormal state of the battery pack 110 is detected, the battery controller 120 may notify the vehicle controller of the abnormal state of the battery pack 110. For example, when the battery controller 120 detects an abnormal state of the current sensor 130, the battery controller 120 may notify the vehicle controller of the abnormal state of the current sensor 130.

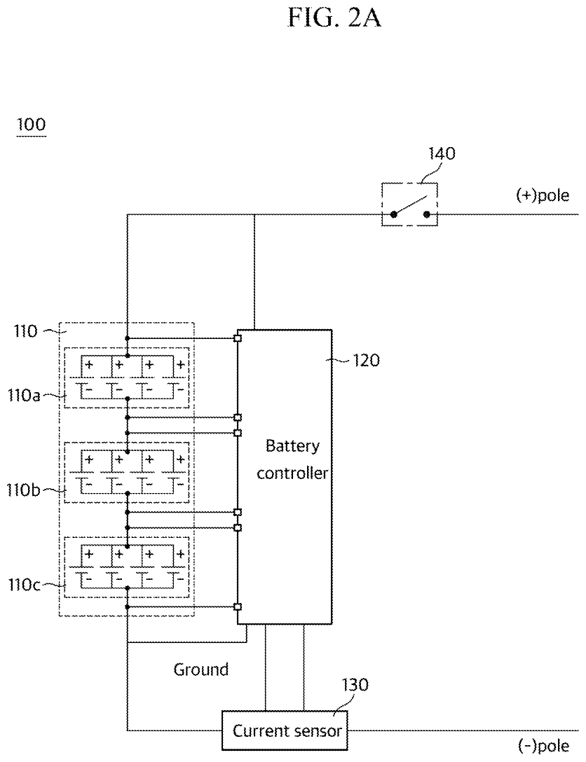

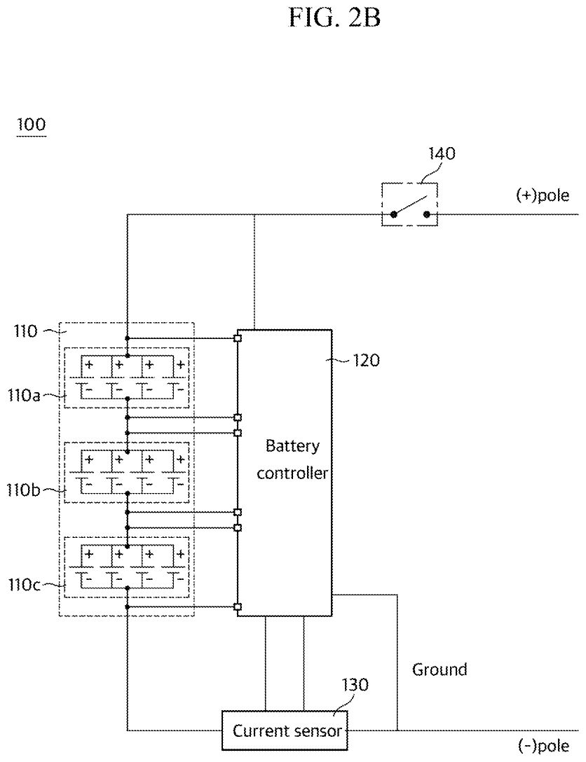

FIGS. 2A and 2B are diagrams illustrating the battery module 100 according to aspects of the disclosure. FIG. 2A depicts the ground line of the battery controller 120 directly connected to the anode terminal of the battery pack 110 while FIG. 2b depicts the ground line of the battery controller 120 installed in a path including the current detecting resistor of the current sensor 130. The battery module 100 illustrated in FIGS. 2A and 2B may include the battery pack 110, the battery controller 120, the current sensor 130, and a relay 140. The battery pack 110 may include a plurality of batteries 110a, 110b, and 110c. The plurality of batteries 110a, 110b, and 110c may be connected in series. Each of the plurality of batteries 110a, 110b and 110c may include a plurality of battery cells. The plurality of battery cells may be connected in parallel.

Referring to FIG. 2A, the current sensor 130 may be electrically connected to the current path formed by the battery pack 110. The battery controller 120 is connected to the battery pack 110 and may monitor and estimate information about various states of the battery pack 110. The ground line of the battery controller 120 may be directly connected to the anode terminal of the battery pack 110. For example, the ground line of the battery controller 120 may be connected between the anode terminal of the battery pack 110 and the current detecting resistor of the current sensor 130.

The battery controller 120 may be directly connected to both ends, e.g., the cathode terminal and the anode terminal, of the battery pack 110, and may monitor the state of the battery pack 110. In this example, the current sensor 130 may measure the current, or charging/discharging current, coming out of or entering the battery pack 110. Here, the current sensor 130 may not measure the current consumption of the battery controller 120 itself. For example, if a situation where the current detecting resistor of the current sensor 130 is shorted and the current value cannot be properly measured, the measured value of the current sensor 130 may be 0 A. Even if the battery pack 110 is in a state where it is not used, e.g., sleep mode, since the current does not flow from the battery pack 110, the measured value of the current sensor 130 may be 0 A.

The consumption current of the battery controller 120 may refer to the current required for the battery controller 120 to operate. The consumption current of the battery controller 120 may be, for example, 100 to 200 mA. The expected consumption current range of the battery controller 120 may be set for each operation mode of the battery pack 110. For example, when the battery pack 110 is in the sleep mode, the expected consumption current range of the battery controller 120 may be set to 100 to 200 mA, and when the battery pack 110 is in a discharge mode, the expected current consumption range of the battery controller 120 may be set to 200 to 300 mA. Therefore, if the detection result of the current sensor 130 is 110 mA, the current consumption of the battery controller 120 is 110 mA, and the battery controller 120 may determine that the current battery pack 110 is in the sleep mode. The described consumption current values are exemplary and may change depending on the type of battery and type of vehicle.

If the measured value of the current sensor 130 is 0 A, it may simply be in a normal state in which the battery pack 110 is not used, or it may be an abnormal state in which the current detecting resistor of the current sensor 130 is shorted. Using only the measurement result of the current sensor 130 thus cannot clearly determine whether the current detecting resistor of the current sensor 130 is short-circuited. Whether the current detecting resistor of the current sensor 130 is shorted may be determined by combining measurement results of the current sensor 130, a battery cell voltage, and external information.

Referring to FIG. 2B, the ground line of the battery controller 120 is not directly connected to the anode terminal of the battery pack 110 but may be installed in the current path including the current detecting resistor of the current sensor 130. For example, one end of the current detecting resistor may be connected to the battery pack 110, and the other end of the current detecting resistor may be connected to the ground line of the battery controller 120.

Since the battery controller 120 is connected to the path including the battery pack 110 and the current sensor 130, the current sensor 130 may measure the charging and discharging current of the battery pack 110 as well as the consumption current of the battery controller 120. Here, the battery controller 120 may not only monitor the state of the battery pack 110 but also monitor the state of the current sensor 130. For example, when the battery pack 110 is in a state where it is not used, e.g., the sleep mode, the current does not flow from the battery pack 110, but the battery controller 120 is in a normally operating state, and thus the measured value of the current sensor 130 may be the consumption current value of the battery controller 120, e.g., 100 to 200 mA. However, when the current detecting resistor of the current sensor 130 is shorted and the current value cannot be properly measured, the measured value of the current sensor 130 may be 0 A. The battery controller 120 thus may determine whether the current detecting resistor of the current sensor 130 is shorted using the measurement result of the current sensor 130.

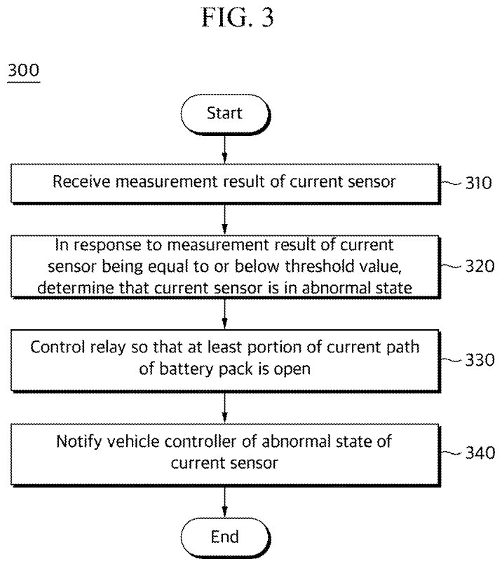

FIG. 3 is a processing flow diagram of the battery module 100 according to aspects of the disclosure. The processing flow diagram 300 may be performed by a battery controller, such as the battery controller 120 as depicted in FIG. 1.

In operation 310, the battery controller 120 receives a measurement result of the current sensor 130. The battery controller 120 may receive the measurement result regarding the current measured by the current sensor 130.

In operation 320, in response to the measurement result of the current sensor 130 being equal to or below a threshold value, the battery controller 120 determines that the current sensor 130 is in an abnormal state. The threshold value refers to a value that is set to determine whether the current sensor 130 is abnormal and may be predetermined based on the current consumption of the battery controller 120. For example, if the consumption current of the battery controller 120 is 120 mA, a user may set the threshold to be 100 mA. If the measurement result of the current sensor 130 is equal to or below the threshold value, the battery controller 120 may determine an abnormal state in which the current sensor 130 cannot measure the consumption current of the battery controller 120 or the state in which the current detecting resistor of the current sensor 130 is shorted.

In operation 330, the battery controller 120 controls a relay, e.g., the relay 140, so that at least a portion of the current path of the battery pack 110 is open. In response to the determination that the current sensor 130 is in an abnormal state, the battery controller 120 may control the relay to open at least a portion of the current path of the battery pack 110. For example, when it is determined that current sensor 130 is in an abnormal state, the battery controller 120 may open the current path to prevent the current from flowing in the battery pack 110 to prevent battery accidents from occurring.

In operation 340, the battery controller 120 notifies the vehicle controller of the abnormal state of the current sensor 130. When it is determined that the current sensor 130 is in an abnormal state, the battery controller 120 may notify the vehicle controller of the abnormal state of the current sensor 130. For example, the battery controller 120 may notify the vehicle controller that there is a problem with the current sensor 130, so that immediate follow-up procedures may be performed.

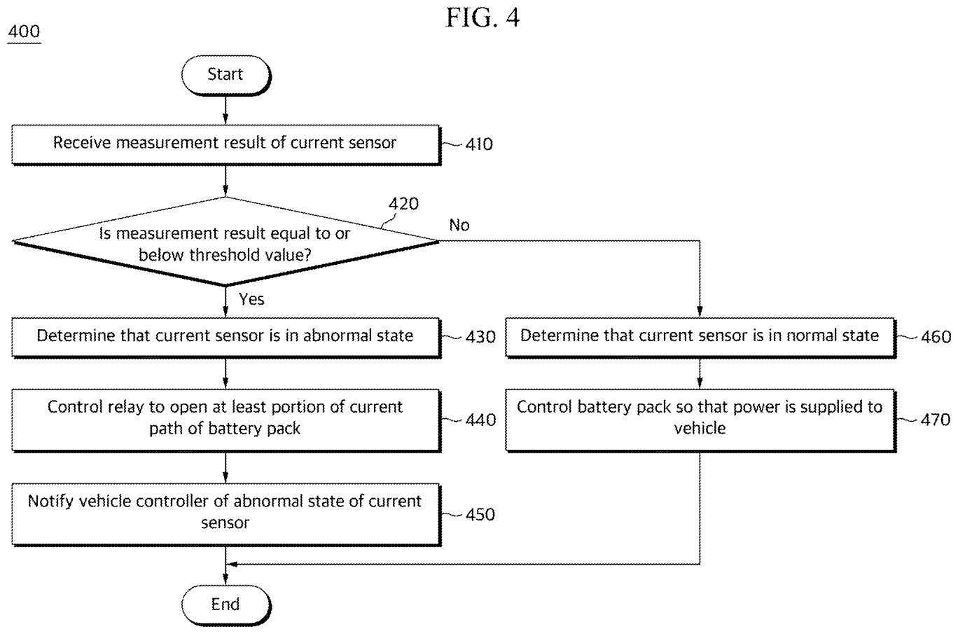

FIG. 4 is a processing flow diagram of the battery module 100 according to aspects of the disclosure. The processing flow diagram 400 may be performed by a battery controller, such as the battery controller 120 as depicted in FIG. 1. Content that overlaps with the content described with respect to FIG. 3 will be omitted.

In operation 410, the battery controller 120 receives a measurement result of the current sensor 130. In operation 420, the battery controller 120 compares the measurement result received from the current sensor 130 with a threshold value. The threshold value is a value that is set to determine whether the current sensor 130 is abnormal, and may be determined based on the current consumption of the battery controller 120.

If the measurement result is equal to or below the threshold value, in operation 430, the battery controller 120 determines that the current sensor 130 is in an abnormal state.

In response to the measurement result being equal to or below a threshold value, the battery controller 120 may determine the current sensor 130 is in the abnormal state in which the current detecting resistor of the current sensor 130 is short-circuited.

In operation 440, the battery controller 120 controls the relay to open at least a portion of the current path of the battery pack 110 in response to determining that the current sensor 130 is in an abnormal state.

In operation 450, in response to the determination that the current sensor 130 is in an abnormal state, the battery controller 120 notifies the vehicle controller of the abnormal state of the current sensor 130.

When the measurement result exceeds the threshold, in operation 460, the battery controller 120 determines that the current sensor 130 is in a normal state. The battery controller 120 may determine the measurement result of the current sensor 130 using a current consumption of the battery controller 120, and the battery controller 120 may determine that the current sensor 130 is in a normal state.

In operation 470, in response to the determination that the current sensor 130 is in a normal state, the battery controller 120 controls the battery pack 110 so that power is supplied to the vehicle. When the required power corresponding to the required torque is requested from the vehicle controller, the battery controller 120 may control the battery pack 110 to output required power corresponding to the torque required for the motor of the vehicle.

Further, when the current sensor 130 is in the normal state, the battery controller 120 may obtain information about the battery state by applying the measurement result of the current sensor 130 to a SoX process. The SoX process may include at least one of a SoC process, a SoP process, and/or a SoH process. Information about the battery state may include at least one of a battery SoC, a battery SoP, and/or a battery SoH, respectively. For example, the battery controller 120 may obtain information about the battery SoC by applying the measurement result of the current sensor 130 to the SoC process.

Before supplying a large amount of power to a motor of a vehicle, the battery controller 120 may control the relay in order for the current path of the battery pack 110 to form a closed circuit, and while the motor of the vehicle is not running, based on the measurement result of the current sensor 130, the battery controller 120 may determine the state of the current sensor 130. For example, the battery controller 120 may form a closed circuit for power supply even before supplying a large amount of power to the motor of the vehicle, and determine the state of the current sensor 130 in advance before the motor is driven.

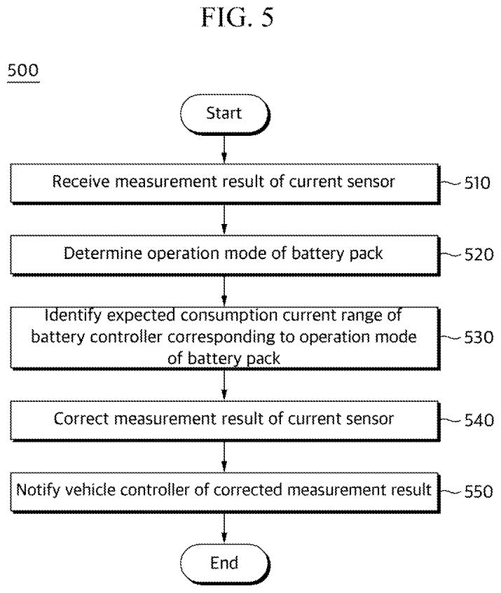

FIG. 5 is a processing flow diagram of the battery module 100 according to aspects of the disclosure. The processing flow diagram 500 may be performed by a battery controller, such as the battery controller 120 as depicted in FIG. 1.

In operation 510, the battery controller 120 receives a measurement result of the current sensor 130.

In operation 520, the battery controller 120 determines the operation mode of the battery pack 110. For example, the operation mode of the battery pack 110 may include a sleep mode, a discharge mode, and/or a charge mode. The sleep mode is a mode in which in a state where the vehicle does not start, there is no request from the vehicle to output power to the battery pack 110, and the sleep mode may indicate a mode in which the battery pack 110 does not operate. In the sleep mode, there is no current charging or discharging from the battery pack 110. Even when the battery pack 110 is in the sleep mode, monitoring of the battery pack 110 is performed, and thus the battery controller 120 may operate, and the current consumption may occur accordingly.

The discharge mode is a mode in which power is output from the battery pack 110 and may indicate a mode in which, while the vehicle is driving, in response to a request of a user, the vehicle controller requests the battery controller 120 to output the required power according to the required torque, and accordingly, the required power is output.

In the discharge mode, the current discharging from the battery pack 110 and the consumption current used from the battery controller 120 may occur. The charge mode is a mode for charging the battery pack 110 and may indicate a mode in which the battery pack 110 is charged through an external charging device or the battery pack 110 is charged according to regenerative braking.

The battery controller 120 may determine the current operation mode of the battery pack 110. Since the battery controller 120 monitors the battery pack 110 in real time, the battery controller 120 may know what the current operation mode of the battery pack 110 is.

In operation 530, the battery controller 120 identifies the expected consumption current range of the battery controller 120 corresponding to the operation mode of the battery pack 110. The consumption current of the battery controller 120 may vary depending on the operation mode of the battery pack 110. Therefore, the range of the expected consumption current of the battery controller 120 may be set for each operation mode of the battery pack 110. For example, when the battery pack 110 is in the sleep mode, the expected current consumption range of the battery controller 120 may be set to 100 to 200 mA, when the battery pack 110 is in the discharge mode, the expected current consumption range of the battery controller 120 may be set to 200 to 300 mA, and when the battery pack 110 is in the charge mode, the expected current consumption range of the battery controller 120 may be set to 250 to 350 mA. For example, if the current operation mode of the battery pack 110 is the discharge mode, the battery controller 120 may identify that the consumption current is 200 to 300 mA. Alternatively, or additionally, the expected consumption current may be set to a specific value rather than a range.

In operation 540, the battery controller 120 corrects the measurement result of the current sensor 130. The battery controller 120 may correct the measurement result of the current sensor 130 by subtracting the identified expected consumption current from the measurement result of the current sensor 130. The pure charging/discharging current of the battery pack 110 that does not reflect the consumption current of the battery controller 120 may be calculated.

In operation 550, the battery controller 120 notifies the vehicle controller of the corrected measurement result.

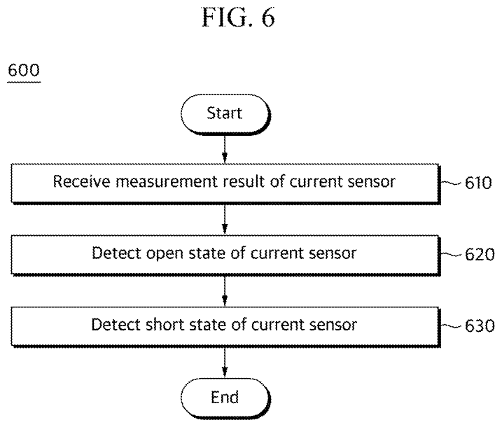

FIG. 6 is a processing flow diagram of the battery module 100 according to aspects of the disclosure. The processing flow diagram 600 may be performed by a battery controller, such as the battery controller 120 as depicted in FIG. 1.

In operation 610, the battery controller 120 of the battery module 100 receives the measurement result of the current sensor 130.

In operation 620, the battery controller 120 detects an open state of the current sensor 130. In a situation where the voltage of a plurality of battery cells included in the battery pack 110 does not rise or fall suddenly, the battery controller 120 may determine whether the current detecting resistor of the current sensor 130 is open based on the detection result of the current sensor 130. When it is determined that the current sensor 130 is open, the battery controller 120 may determine that there is an abnormal state, and may control the relay so that at least some of the current path of the battery pack 110 is opened.

In operation 630, the battery controller 120 detects a short state of the current sensor 130. Based on the measurement result of the current sensor 130, the battery controller 120 may determine whether the current detecting resistor of the current sensor 130 is shorted. The method for diagnosing the short state of the current sensor 130 is the same as the method described in FIGS. 3 and 4. If it is determined that the current sensor 130 is shorted, the battery controller 120 may determine that there is an abnormal state and may control the relay so that at least some of the current path of the battery pack 110 is opened.

When it is determined that the current detecting resistor of the current sensor 130 is not open or shorted, the battery controller 120 may determine that the current sensor 130 is in a normal state and control the battery pack 110 so that power is supplied to the vehicle in response to the required torque.

Throughout the specification, when a part is described as “comprising or including” a component, that part does not exclude another component but may further include another component unless otherwise stated. Furthermore, terms such as “ . . . unit,” “. . . group,” and/or “ . . . module” described in the specification mean a unit that processes at least one function or operation, which may be implemented as hardware, software, or a combination thereof.

Expression “at least one of a, b, or c” described throughout the specification may include “a alone,” “b alone,” “c alone,” “a and b,” “a and c,” “b and c” or “all of a, b and c.”

It will be understood that each block of a flowchart diagram and a combination of the flowchart diagrams may be performed by computer program instructions. The computer program instructions may be embodied in a processor of a general-purpose computer or a special purpose computer, or may be embodied in a processor of other programmable data processing equipment. Thus, the instructions, executed via a processor of a computer or other programmable data processing equipment, may generate a part for performing functions described in the flowchart blocks. To implement a function in a particular manner, the computer program instructions may also be stored in a computer-usable or computer-readable memory that may direct a computer or other programmable data processing equipment. Thus, the instructions stored in the computer-usable or computer readable memory may be produced as an article of manufacture containing an instruction part for performing the functions described in the flowchart blocks. The computer program instructions may be embodied in a computer or other programmable data processing equipment. Thus, a series of operations may be performed in a computer or other programmable data processing equipment to create a computer-executed process, and the computer or other programmable data processing equipment may provide steps for performing the functions described in the flowchart blocks.

Additionally, each block may represent a module, a segment, or a portion of code that includes one or more executable instructions for executing a specified logical function(s). It should also be noted that, in some implementations, the functions recited in the blocks may occur out of order. For example, two blocks shown one after another may be performed substantially at the same time, or the blocks may sometimes be performed in the reverse order according to a corresponding function.

A device or a terminal according to aspects of the disclosure may include a processor, a memory for storing and executing program data, permanent storage such as disk drives, communication ports to communicate with external devices, and/or user interface devices such as touch panels, keys, and buttons. Methods implemented as software modules or algorithms are computer readable codes or program instructions executable on the processor, and may be stored on a transitory or non-transitory computer-readable recording medium. Here, the computer-readable recording medium includes a magnetic storage medium (for example, a read-only memory (ROM), a random-access memory (RAM), a floppy disk and a hard disk) and an optically readable medium (for example, a CD-ROM, a digital versatile disc (DVD)). The computer-readable recording medium may be distributed among network-connected computer systems, so that a computer-readable code may be stored and executed in a distributed manner. The medium may be readable by a computer, stored in a memory, and executed on a processor.

Aspects of the disclosure may be represented by functional block elements and various processing steps. The functional blocks may be implemented in any number of hardware and/or software configurations that perform specific functions. For example, aspects of the disclosure may adopt integrated circuit configurations, such as memory, processing, logic and/or look-up table, that may execute various functions by the control of one or more microprocessors or other control devices. Aspects of the disclosure may be implemented in a programming or scripting language such as C, C++, Java, assembler, Python, etc., including various algorithms implemented as a combination of data structures, processes, routines, and/or other programming constructs. Functional aspects may be implemented in an algorithm running on one or more processors. Further, the examples may adopt the existing art for electronic environment setting, signal processing, and/or data processing.

Unless otherwise stated, the foregoing alternative examples are not mutually exclusive but may be implemented in various combinations to achieve unique advantages. As these and other variations and combinations of the features discussed above can be utilized without departing from the subject matter defined by the claims, the foregoing description of the examples should be taken by way of illustration rather than by way of limitation of the subject matter defined by the claims. In addition, the provision of the examples described herein, as well as clauses phrased as “such as,” “including” and the like, should not be interpreted as limiting the subject matter of the claims to the specific examples; rather, the examples are intended to illustrate only one of many possible implementations. Further, the same reference numbers in different drawings can identify the same or similar elements.

1-13. (canceled)

14. A battery module comprising:
a battery pack;
a current sensor comprising a current detecting resistor electrically connected to a current path formed by the battery pack; and
a battery controller configured to control the battery pack and determine whether the current sensor is abnormal based on a measurement result of the current sensor;
wherein the current detecting resistor has one end that is connected to the battery pack and another end that is connected to a ground line of the battery controller.

15. The battery module of claim 14, wherein the battery controller is further configured to determine that the current sensor is in an abnormal state based on the measurement result of the current sensor being equal to or below a threshold value.

16. The battery module of claim 15, wherein the battery controller is further configured to notify a vehicle controller of the abnormal state of the current sensor based on a determination that the current sensor is in the abnormal state.

17. The battery module of claim 15, wherein the battery controller is further configured to control a relay to open at least a part of the current path of the batty pack based on the determination that the current sensor is in the abnormal state.

18. The battery module of claim 15, wherein the threshold value is determined based on a consumption current of the battery controller.

19. The battery module of claim 15, wherein an expected consumption current range of the battery controller is set for each operation mode of the battery pack.

20. The battery module of claim 19, wherein the battery controller is further configured to:
based on the measurement result of the current sensor, determine an operation mode of the battery pack;
identify an expected consumption current range of the battery controller corresponding to the operation mode of the battery pack;
based on the identified expected consumption current range, correct the measurement result of the current sensor; and
notify a vehicle controller of the corrected measurement results.

21. The battery module of claim 15, wherein the battery controller is further configured to:
based on the measurement result of the current sensor exceeding the threshold value, determine that the current sensor is in a normal state; and
based on a determination that the current sensor is in the normal state, control the battery pack to supply power to a vehicle.

22. The battery module of claim 14, wherein the battery controller is further configured to obtain information on a battery state by applying the measurement result of the current sensor to a SoX process.

23. The battery module of claim 22, wherein the SoX process comprises at least one of a state of charge (SoC) process, a state of power (SoP) process, or a state of health (SoH) process, and the information on the battery state comprises at least one of a battery SoC, a battery SoP, or a battery SoH, respectively.

24. The battery module of claim 14, wherein the current detecting resistor is a shunt resistor.

25. The battery module of claim 14, wherein the battery controller is further configured to:
before supplying an amount of power to a motor of the vehicle, control a relay for a closed circuit to be formed in the current path of the battery pack; and
while the motor of the vehicle is not running, determine a state of the current sensor based on the measurement result of the current sensor.

26. A method of determining a state of a current sensor by a battery controller included in a battery module, the method comprising:
receiving a measurement result of a current sensor comprising a current detecting resistor electrically connected to a current path that formed by a battery pack; and
based on the measurement result of the current sensor, determining whether the current sensor is abnormal;
wherein the current detecting resistor has one end that is connected to the battery pack and another end that is connected to a ground line of the battery controller.

27. The method of claim 26, further comprising determining that the current sensor is in an abnormal state based on the measurement result of the current sensor being equal to or below a threshold value.

28. The method of claim 27, further comprising notifying a vehicle controller of the abnormal state of the current sensor based on a determination that the current sensor is in the abnormal state.

29. The method of claim 27, further comprising controlling a relay to open at least a part of the current path of the batty pack based on the determination that the current sensor is in the abnormal state.

30. The method of claim 27, wherein the threshold value is determined based on a consumption current of the battery controller.

31. The method of claim 27, wherein an expected consumption current range of the battery controller is set for each operation mode of the battery pack.

32. The method of claim 31, further comprising:
based on the measurement result of the current sensor, determining an operation mode of the battery pack;
identifying an expected consumption current range of the battery controller corresponding to the operation mode of the battery pack;
based on the identified expected consumption current range, correcting the measurement result of the current sensor; and
notifying a vehicle controller of the corrected measurement results.

33. A non-transitory computer readable medium for storing instructions that, when executed by one or more processors, cause the one or more processors to perform operations for a method for determining a state of a current sensor by a battery controller included in a battery module, the method comprising:
receiving a measurement result of a current sensor comprising a current detecting resistor electrically connected to a current path that formed by a battery pack; and
based on the measurement result of the current sensor, determining whether the current sensor is abnormal;
wherein the current detecting resistor has one end that is connected to the battery pack and another end that is connected to a ground line of the battery controller.
